(19) United States
(12) Patent Application Publication
(10) Pub. No.: US 2025/0056920 A1
(43) Pub. Date: Feb. 13, 2025

(54) DIE REPAIR PROCESS IN MICROLED DISPLAY FABRICATION

(71) Applicant: Applied Materials, Inc., Santa Clara, CA (US)

(72) Inventors: Peiwen LIU, Fremont, CA (US); Uma SRIDHAR, Sunnyvale, CA (US); Hyunsung BANG, Sunnyvale, CA (US); Kai DING, Cupertino, CA (US); Jeffrey L. FRANKLIN, Albuquerque, NM (US); Mingwei ZHU, San Jose, CA (US); Hou T. NG, Campbell, CA (US); Nag B. PATIBANDLA, Santa Clara, CA (US)

(21) Appl. No.: 18/797,189

(22) Filed: Aug. 7, 2024

Related U.S. Application Data
(60) Provisional application No. 63/518,487, filed on Aug. 9, 2023.

(51) Int. Cl. H01L 33/00; H01L 25/075

(52) U.S. Cl. CPC H01L 33/005; H01L 25/0753

(57) ABSTRACT

The present disclosure provides devices and methods for repairing dice during micro-LED display fabrication. The devices include a backplane. The backplane has a plurality of backplane electrodes. Each backplane electrode includes a first material. A plurality of micro-LEDs having a plurality of micro-LED electrodes is included in the device. Each micro-LED electrode includes a second material. Each micro-LED electrode is bonded to each backplane electrode with an alloy of the first material and the second material therebetween. At least one backplane electrode is bonded to the micro-LED electrode via a repair material. The device includes a plurality of subpixel isolation (SI) structures formed over the backplane. The SI structures define wells of sub-pixels. Each well includes a respective micro-LED between adjacent SI structures. The sub-pixels have a color conversion material disposed in the wells.

### CROSS-REFERENCE TO RELATED APPLICATIONS

This application claims priority to U.S. Provisional Patent Application Ser. No. 63/518,487 filed on Aug. 9, 2023, which is herein incorporated by reference in its entirety.

### BACKGROUND

### Field

Embodiments of the present disclosure generally relate to a method and apparatus for repairing dice during micro-LED display fabrication.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like.

An LED panel that uses micron-scale LEDs based on III-V semiconductor technology (also called micro-LEDs or micro-LEDs) would have a variety of advantages as compared to organic LEDs (OLEDs), e.g., higher energy efficiency, brightness, and lifetime, as well as fewer material layers in the display stack, which can simplify manufacturing. However, there are challenges to fabrication of micro-LED panels. Micro-LEDs having different color emission (e.g., red, green, and blue pixels) need to be fabricated on different substrates through separate processes. Integration of the multiple colors of micro-LED devices onto a single panel requires a pick-and-place step to transfer the micro-LED devices from their original donor substrates to a destination substrate. This often involves modification of the LED structure or fabrication process, such as introducing sacrificial layers to ease die release. In addition, stringent requirements on placement accuracy (e.g., less than 1 μm) limit either the throughput, the final yield, or both.

Achieving a high light-up yield (e.g., 99.99%) in high pixels per inch (PPI) micro-LED display fabrication is important to display performance. However, the mass transfer process used in some micro-LED display fabrication, which encompasses millions of micro-LED dice, often yields a lower number of dice that are successfully transferred and light up. Conventional die repair processes involve physical die repair during the transfer processes to double interposers, which requires new adhesive interposer materials and more procedures, thus resulting in higher costs and lower throughput.

Thus, it is desirable to develop die repair processes for high-volume manufacturing of micro-LED displays.

### SUMMARY

In an embodiment, the present disclosure generally provides devices. The devices include a backplane. The backplane has a plurality of backplane electrodes. Each backplane electrode includes a first material. A plurality of micro-LEDs having a plurality of micro-LED electrodes is included in the device. Each micro-LED electrode includes a second material. Each micro-LED electrode is bonded to each backplane electrode with an alloy of the first material and the second material therebetween. At least one backplane electrode is bonded to the micro-LED electrode via a repair material. The device includes a plurality of subpixel isolation (SI) structures formed over the backplane. The SI structures define wells of sub-pixels. Each well includes a respective micro-LED between adjacent SI structures. The sub-pixels have a color conversion material disposed in the wells.

In another embodiment, the present disclosure generally provides methods for repairing dice during micro-LED display fabrication. The methods include determining a first map of the micro-LED display. The first map includes one or more locations of a defective micro-LED. The defective micro-LED is repaired at each location of the one or more locations of the first map, in which repairing the defective micro-LED includes trimming the defective micro-LED from a backplane of the micro-LED to expose a backplane electrode. A repair material is disposed on the backplane electrode. A repair micro-LED is disposed on the repair material.

In another embodiment, the present disclosure generally provides systems. The systems include an inspective device operable to determine a first map of a micro-LED display, determine a second map of the micro-LED display, and determine a third map of the micro-LED display. The systems include a first laser configured to trim a micro-LED on the micro-LED display based on the second map. The systems include an applicator configured to dispose a repair material to the micro-LED display based on the third map. The systems include a second laser configured to perform a laser lift off on a repair micro-LED on a substrate based on the first map.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A and 1B are schematic, cross-sectional views of a micro-LED display pixel architecture, according to embodiments.

FIG. 2 is a schematic, cross-sectional view of a backplane being inspected and tested by an inspection device, according to embodiments.

FIGS. 3A-3D depict a set of exemplary maps of a backplane, according to embodiments.

FIG. 4 schematically depicts a defective die laser trim-off operation, according to embodiments.

FIG. 5 schematically depicts a backplane bump repair operation, according to embodiments.

FIGS. 6A-6B schematically depict a repair laser lift off operation and a separation and transfer operation, according to embodiments.

FIGS. 7A-7B schematically depict a laminating to second polymer operation and a separation and transfer operation, according to embodiments.

FIGS. 8A-8B schematically depict a repair bonding to backplane operation and a second polymer separation operation, according to embodiments.

FIG. 9 is a schematic, cross-sectional view of a backplane being inspected and tested by an inspection device, according to embodiments.

FIGS. 10A-10D depict a set of exemplary maps of a backplane, according to embodiments.

FIG. 11 schematically depicts a defective die laser trim-off operation, according to embodiments.

FIG. 12 schematically depicts a backplane bump repair operation, according to embodiments.

FIGS. 13A-13B schematically depict a repair laser lift off operation and a separation and transfer operation, according to embodiments.

FIGS. 14A-14B schematically depict a laminating to second polymer operation and a separation and transfer operation, according to embodiments.

FIGS. 15A-15B schematically depict a repair bonding to backplane operation and a second polymer separation operation, according to embodiments.

FIG. 16 is a flow diagram of a method 1600 of repairing a micro-LED display, according to embodiments.

FIGS. 17A-17C schematically depicts a system, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to a methods and systems for repairing dice during micro-LED display fabrication. Achieving a high light-up yield (e.g., 99.99%) in high pixels per inch (PPI) micro-LED display fabrication is important to display performance. However, the mass transfer process used in some micro-LED display fabrication, which encompasses millions of micro-LED dice, often yields a lower number of dice that are successfully transferred and light up. Conventional die repair processes involve physical die repair during the transfer processes to double interposers, which requires new adhesive interposer materials and more procedures, thus resulting in higher costs and lower throughput.

In aspects of the present disclosure, an image analysis software or an artificial intelligence (AI) based image analysis software. Additional tools may be included in the repair process that is more efficient than other repair processes.

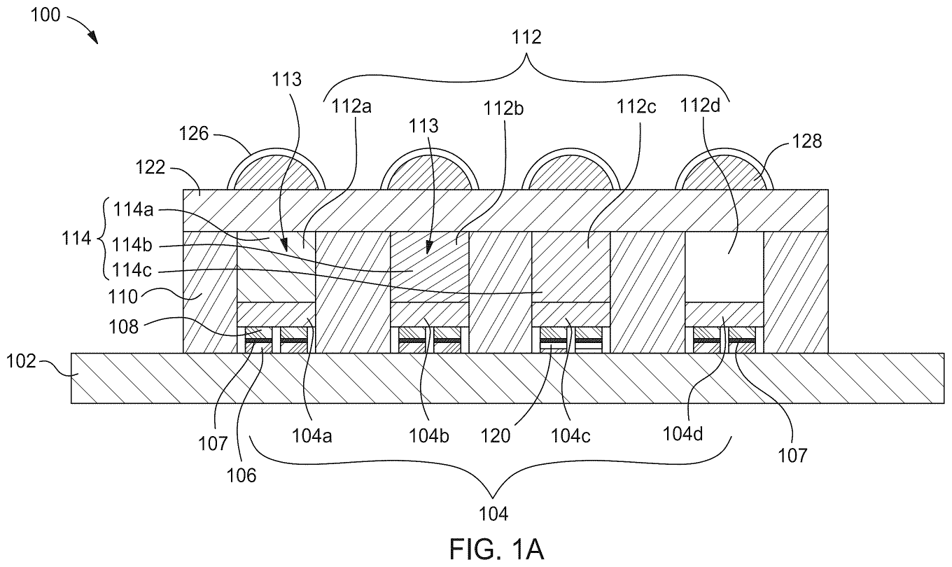

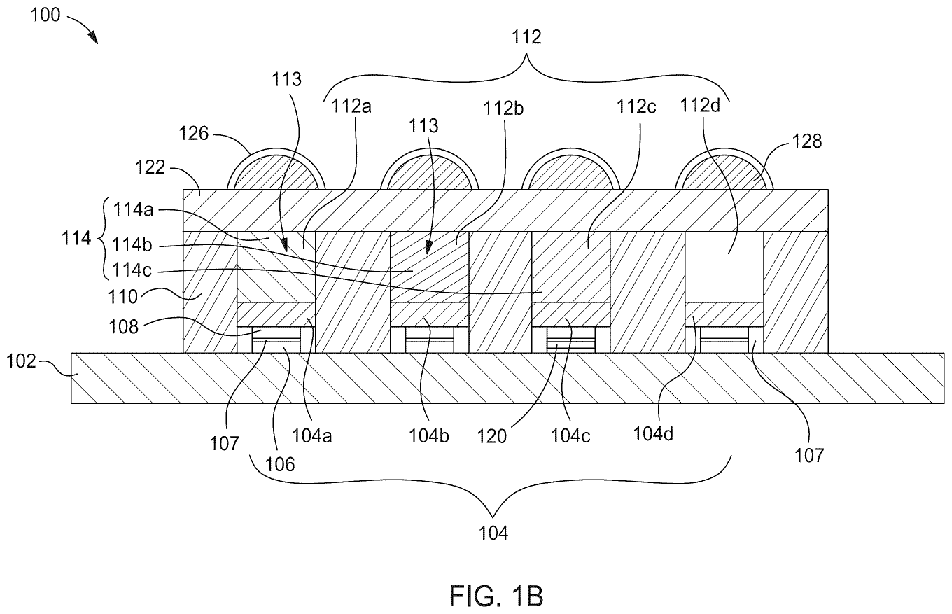

FIG. 1A is a cross-sectional view of a pixel 100. The pixel 100 includes at least three micro-LEDs disposed on a backplane 102. The micro-LEDs are integrated with backplane circuitry so that each micro-LED 104 can be individually addressed. For example, the circuitry of the backplane can include a TFT active matrix array with a thin-film transistor and a storage capacitor (not illustrated) for each micro-LED 104, column address and row address lines, column and row drivers, to drive the micro-LEDs. Alternatively, the micro-LEDs can be driven by a passive matrix in the backplane circuitry. The backplane 102 can be fabricated using conventional complementary metal-oxide silicon (CMOS) process. The micro-LEDS are connected to the backplane 102 via two or more backplane electrodes 106 and two or more micro-LED electrodes 108. At the interface of the two or more backplane electrodes 106 and the two or more micro-LED electrodes 108, is an alloy 107 of the two electrode materials. Additionally, or alternatively, a repair material 120 may be disposed at the interface of the two or more backplane electrodes 106 and the alloy 107 of the two electrode materials. The repair material 120 can include a conductive material, e.g., a metal capable of transmitting a current. The repair material 120 can include a metal configured to adhere the backplane electrodes 106 to the alloy 107. For example, the repair material 120 can include silver and/or indium.

In certain embodiments the two or more backplane electrodes 106 include a first metal of a first material. The first material includes, but is not limited to, gold, indium, tin, silver, aluminum, platinum, or combinations thereof. In certain embodiments, the two or more micro-LED electrodes 108 include a second metal of a second material. The second material includes, but is not limited to, gold, silver, aluminum, platinum, indium, or combinations thereof. In certain embodiments, the first material and the second material are different. An alloy 107 of the first material and the second material is formed from the method described herein. The alloy 107 bonds the two or more backplane electrodes 106 to the two or more micro-LED electrodes 108 to secure the micro-LEDs to the backplane 102. In certain embodiments, the two or more backplane electrodes 106 include indium and the two or more micro-LED electrodes 108 include gold to form the alloy 107 of indium and gold. In other embodiments, the two or more backplane electrodes 106 may include gold and the two or more micro-LED electrodes 108 may include indium to form an alloy 107 of gold and indium. In certain embodiments, the alloy 107 has a ratio of the first material to the second material (i.e., first material:second material). The ratio of first material to second material is about 1:3 to about 3:1. The ratio of first material to second material depends on the material used to form the alloy 107. Each micro-LED 104 configured to emit UV light in a first wavelength range. The UV light may be white light. The micro-LEDs may be LEDs.

Subpixel isolation (SI) structures 110 are disposed over, and in some embodiments on, the backplane 102. The adjacent SI structures define the respective well of at least three sub-pixels. A micro-LED 104 is disposed in each well 113 between the adjacent SI structures. Each well 113 has a width from about 0.5 μm to about 40 μm, such as about 2 μm to about 30 μm. The SI structures 110 have a width from about 0.1 μm to about 15 μm such as 1 μm to 10 μm. The SI structures 110 may include organic material, such as epoxy-based photoresist.

The sub-pixels 112 include a first sub-pixel 112a with a red color conversion material 114a disposed in the well 113 of the first sub-pixel 112a, a second sub-pixel 112b with a blue color conversion material 114b disposed in the well 113 of the second sub-pixel 112b, and a third sub-pixel 112c with a green color conversion material 114c disposed in the well 113 of the third sub-pixel 112c. When a micro-LED 104a of the first sub-pixel 112a is turned on the red color conversion material 114a will convert the light emitted from micro-LED 104a into red light. When a micro-LED 104b of the second sub-pixel 112b is turned on the blue color conversion material 114b will convert the light emitted from micro-LED 104b into blue light. When a micro-LED 104c of the third sub-pixel 112c is turned on the green color conversion material 114c will convert the light emitted from micro-LED 104c into green light. In one embodiment, the pixel 100 includes a fourth sub-pixel 112d. As shown in FIG. 1A, the fourth sub-pixel 112d does not include a color conversion material, i.e., color-conversion-layer-free. In some embodiments, the fourth sub-pixel 112d may be later filled with a color conversion material 114 (e.g., a red, green, blue, violet, etc. color conversion material). In another embodiment, the fourth sub-pixel 112d includes a sacrificial material (not shown). In other embodiments, the at least three sub-pixels include the same color conversion material. The fourth sub-pixel 112d may be later filled with a color conversion material 114.

In some embodiments, the color conversion material 114 may include quantum dots (QDs). The quantum dots may be sized to produce wavelengths corresponding to different colors. In one embodiment, the red color conversion material 114a may include quantum dots approximately 6 nm in size. The blue color conversion material 114b may include quantum dots approximately 4 nm in size. The green color conversion material 114c may include quantum dots approximately 2 nm in size. In other embodiments, the color conversion material 114 may include nanostructures, photoluminescent materials, or organic substances.

An encapsulation layer 122 is disposed over, and in some embodiments directly on, a top surface of the SI structures 110 and the sub-pixels 112. The encapsulation layer 122 prevents reactions between the color conversion material 114 and other materials in an ambient environment. The encapsulation layer 122 has a thickness from 10 nm or less and is one of a metal layer, a metal oxide layer, or a silicon containing layer. The encapsulation layer includes, but is not limited to, aluminum oxide, titanium oxide, silicon nitride, tantalum (Ta) hafnium (Hf), tantalum oxide, hafnium oxide, titanium (Ti), aluminum (AI), chromium (Cr), copper (Cu), tungsten (W), zirconium (Zr), or a combination thereof. The encapsulation layer 122 may be deposited using a physical vapor deposition (PVD) process, chemical vapor deposition (CVD), or atomic layer deposition (ALD). The PVD process may include pulsed laser deposition (PLD), thermal evaporation, or electron beam evaporation PVD (EBPVD).

In some embodiments, the pixel 100 includes micro-lenses 128 disposed on the encapsulation layer 122 and over each of the wells 113 of the sub-pixels 112. In some embodiments, a passivation layer 126 is disposed on the micro-lenses 128. In other embodiments, the micro-lenses 128 may be made of a resist material such as photoresist material that blocks UV light. In some embodiments, which can be combined with other embodiments, the pixel 100 includes one backplane electrode 106 coupled to one micro-LED electrode 108, as shown in FIG. 1B.

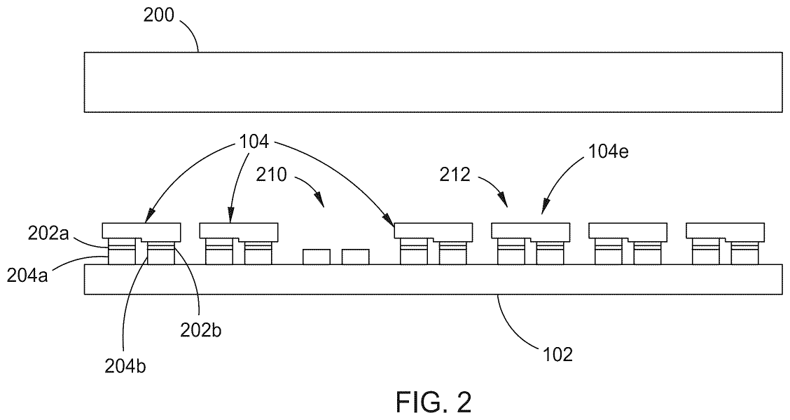

FIG. 2 is a schematic, cross-sectional view of a backplane 102 being inspected and tested by an inspection device 200. The backplane 102 has a plurality of micro-LED 104 bonded to the backplane 102. The micro-LED 104 each have two electrodes 202a and 202b that are each bonded to corresponding electrodes 204a and 204b on the backplane 102. The electrodes 204 may also be referred to herein as solder bumps or bumps. The backplane 102 is illustrated shortly after the micro-LED 104 have been bonded to the backplane 102.

During fabrication of a micro-LED display, after the micro-LED 104 are bonded to the backplane 102, the backplane 102 and the micro-LED 104 are inspected and tested by the inspection device 200. The inspection device may utilize an artificial intelligence (AI) based image analysis software, according an embodiment of the present disclosure. When the backplane 102 and the micro-LED 104 are inspected and tested, the image analysis software makes a record of locations, such as location 210, where a micro-LED 104 should be bonded to the backplane 102 but is not present. The image analysis software may incorporate AI. In an example, when the backplane 102 and the micro-LED 104 are inspected and tested by the inspection device 200, the defective micro-LED die 104e fails to illuminate (i.e., fails to emit light of the correct frequency and/or intensity). The AI based image analysis software also makes a record of locations, such as location 212, where a micro-LED 104 is present but fails to illuminate (e.g., the defective micro-LED die 104e). Making a record of locations 210 and 212 may include determining x and y coordinates on the backplane 102 indicating the locations. The x and y coordinates may be made with reference to a reference point on the backplane 102.

When the inspection device 200 has completed inspection and testing of the backplane 102, the AI based image analysis software may generate a set of maps regarding the backplane 102, according to embodiments of the present disclosure.

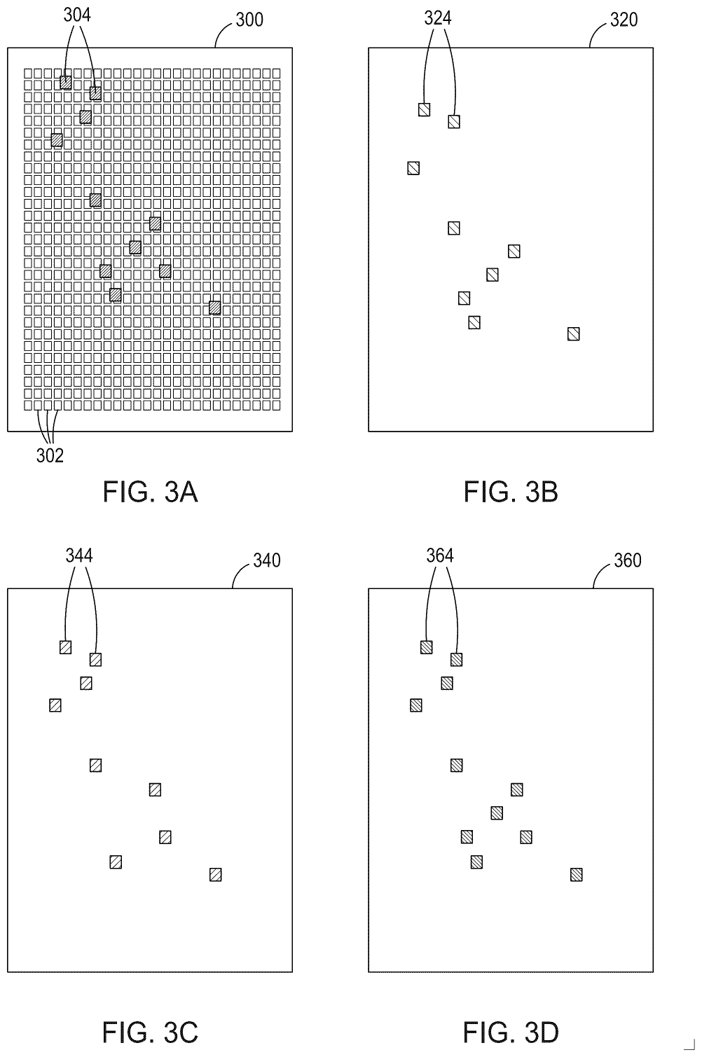

FIGS. 3A-3D depict a set of exemplary maps of a backplane 102 as created by the AI based image analysis software of the inspection device 200, according to embodiments of the present disclosure. FIG. 3A depicts a light-up/mechanical map 300 of the backplane 102. In the light-up/mechanical map 300, dots 302 indicate locations on the backplane 102 where micro-LEDs illuminated properly during an inspection and testing process, while dots 304 indicate locations (e.g., locations 210 and 212) on the backplane 102 where a micro-LED did not illuminate properly during the inspection and testing process.

FIG. 3B depicts a laser trim map 320 of the backplane 102. In the laser trim map 320, dots 324 indicate locations (e.g., locations 212) on the backplane 102 where micro-LEDs are present on the backplane 102, but did not illuminate properly during the inspection and testing process. It may be noted that there are fewer dots 324 on laser trim map 320 than dots 304 on light-up/mechanical map 300.

FIG. 3C depicts a bump repair map 340 of the backplane 102. In the bump repair map 340, dots 344 indicate locations (e.g., locations 210 or 212) on the backplane 102 where the AI based image analysis software determined to repair backplane electrodes. The dots 344 on bump repair map 340 may indicate the same or different locations than the dots 324 indicate on laser trim map 320. Bump repair map 340 may indicate more, the same, or fewer locations that are indicated on laser trim map 320.

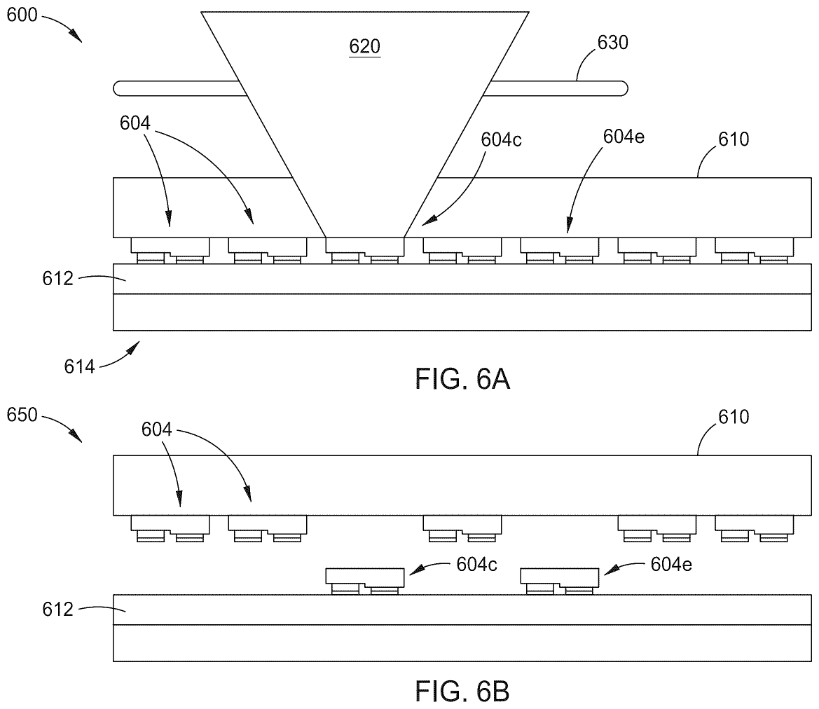

FIG. 3D depicts a laser lift off (LLO) repair map 360 of the backplane 102. In the LLO repair map 360, dots 364 indicate locations (e.g., locations 210 or 212) on the backplane 102 where the AI based image analysis software determined to install a repair micro-LED die (see FIG. 6A). The dots 364 on LLO repair map 360 may indicate the same locations that the dots 304 indicate on light-up/mechanical map 300.

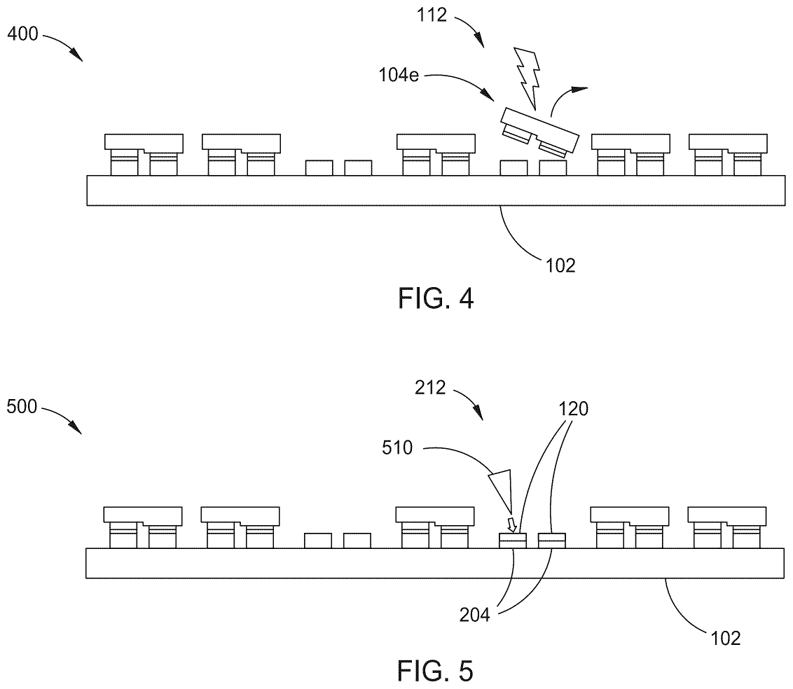

FIG. 4 schematically depicts a defective die laser trim-off operation 400, according to embodiments of the present disclosure. In the defective die laser trim-off operation 400, defective micro-LED die 104e is trimmed (e.g., using a laser) off the backplane 102. Defective micro-LED die 104e may be trimmed off the backplane 102 on the basis of the defective micro-LED die 104e being located at location 212 on the backplane 102 and location 212 being among the locations indicated by dots 324 on laser trim map 320.

FIG. 5 schematically depicts a backplane bump repair operation 500, according to embodiments of the present disclosure. In the backplane bump repair operation 500, repair material 120 (e.g., indium or silver ink) is applied to the electrodes 204 at location 212 by an applicator 510 (e.g., an inkjet printer). Electrodes 204 may be repaired based on the electrodes 204 being located at location 212 on the backplane 102 and location 212 being among the locations indicated by dots 344 on bump repair map 340.

FIGS. 6A-6B schematically depict a repair laser lift off operation 600 and a separation and transfer operation 650, according to embodiments of the present disclosure. When the operation 600 begins, a plurality of repair micro-LED 604 are bonded to a translucent carrier 610 and to a first polymer 612 of a first interposer 614. The repair micro-LED 604 may be of the same type as the micro-LED 104 shown in FIGS. 1 and 2. The translucent carrier 610 may be made of sapphire, for example. During the operation 600, laser light 620 may be transmitted at the repair micro-LED 604. A mask 630 may be formed on the basis of the LLO repair map 360 so that only repair micro-LED 604 at locations indicated by the LLO repair map 360 are exposed to the laser light 620. Repair micro-LED 604c (as shown) and repair micro-LED 604e are exposed to the laser light 620, which causes the repair micro-LED 604c and 604e to debond from the translucent carrier 610.

FIG. 6B schematically depicts the separation and transfer operation 650, according to embodiments of the present disclosure. The translucent carrier 610 is separated from the first interposer 614 during the separation and transfer operation 650. Repair micro-LED 604c and 604e remain attached to the first polymer 612, while the remaining repair micro-LED 604 remain bonded to the translucent carrier 610.

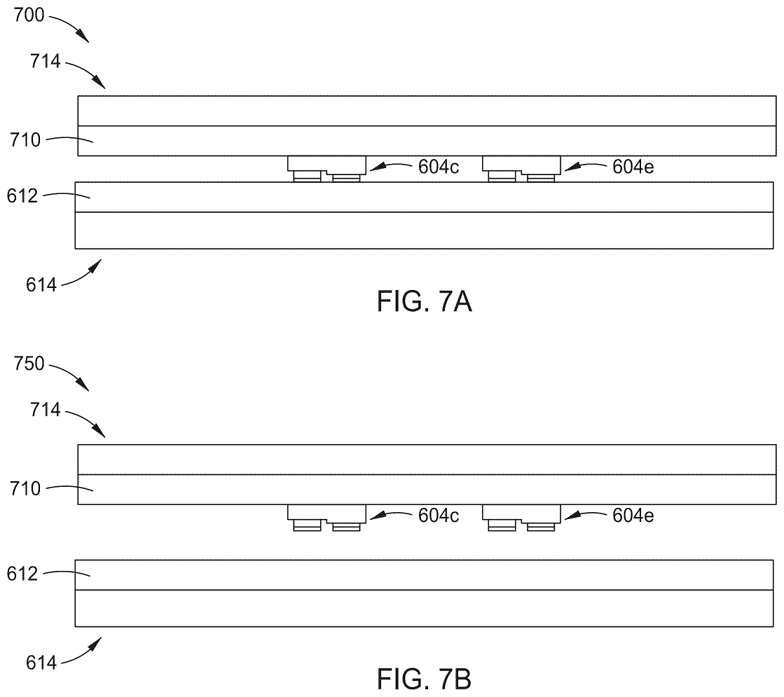

FIGS. 7A-7B schematically depict a laminating to second polymer operation 700 and a separation and transfer operation 750, according to embodiments of the present disclosure. During the laminating to second polymer operation 700, repair micro-LED dice on first polymer 612 (e.g., repair micro-LED 604c and 604e) are bonded to second polymer 710 of a second interposer 714.

FIG. 7B schematically depicts the separation and transfer operation 750, according to embodiments of the present disclosure. The second polymer 710 is separated from the first polymer 612 during the separation and transfer operation 750. Repair micro-LED 604c and 604e remain bonded to the second polymer 710 of second interposer 714.

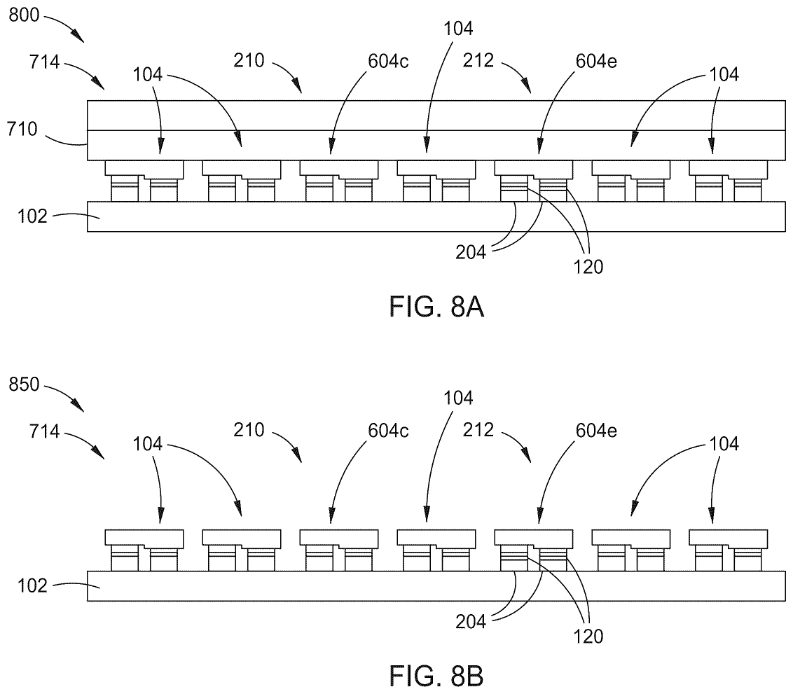

FIGS. 8A-8B schematically depict a repair bonding to backplane operation 800 and a second polymer separation operation 850, according to embodiments of the present disclosure. During the repair bonding to backplane operation 800, repair micro-LED dice (e.g., repair micro-LED 604c and 604e) bonded to second polymer 710 of second interposer 714 are bonded with (e.g., soldered to) electrodes 204 on backplane 102. As depicted, the repair micro-LED dice are bonded with electrodes 204 in locations (e.g., locations 210 and 212) on the backplane 102 that do not have micro-LED 104 present. The repair micro-LED dice may be bonded directly to electrodes 204 or to repair material 120 (e.g., indium or silver ink) applied to electrodes 204 during backplane bump repair operation 500.

FIG. 8B schematically depicts the second polymer separation operation 850, according to embodiments of the present disclosure. The second polymer 710 is separated from the repair micro-LED 604c and 604e during the second polymer separation operation 850. Repair micro-LED 604c and 604e remain bonded with the electrodes 204 on the backplane 102. After completion of the second polymer separation operation 850, the backplane 102 may be considered repaired. The repaired backplane 102 may then be inspected and tested again, as described above with reference to FIG. 2.

A repair process similar to the process depicted in FIGS. 2-8B may be used to repair vertical chips, according to embodiments of the present disclosure.

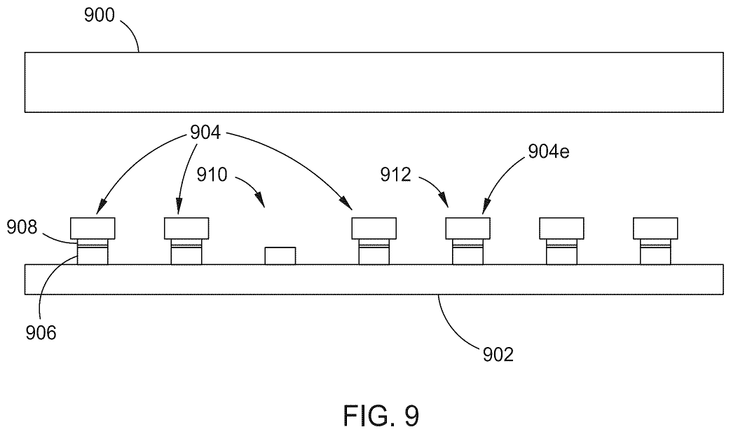

FIG. 9 is a schematic, cross-sectional view of a backplane 902 being inspected and tested by an inspection device 900. The backplane 902 has a plurality of micro-LED vertical chips 904 bonded to the backplane 902. The micro-LED vertical chips 904 each have an electrode 908 that may be bonded (e.g., soldered) to a corresponding electrode on the backplane 902. During operation of the micro-LED vertical chips 904, a second electrode at the top of each micro-LED vertical chip 904 carries electricity to or from that micro-LED vertical chip 904. The electrodes 906 may also be referred to herein as solder bumps or bumps. The backplane 902 is illustrated shortly after the micro-LED vertical chips 904 have been bonded to the backplane 902.

During fabrication of a micro-LED display, after the micro-LED vertical chips 904 are bonded to the backplane 902, the backplane 902 and the micro-LED vertical chips 904 are inspected and tested by the inspection device 900. The inspection device 900 may use inductive coupling to supply electrical energy to the micro-LED vertical chips 904 to perform a non-contact light-up inspection and map-out. The inspection device 900 may utilize an artificial intelligence (AI) based image analysis software, according an embodiment of the present disclosure. When the backplane 902 and the micro-LED vertical chips 904 are inspected and tested, the AI based image analysis software makes a record of locations, such as location 910, where a micro-LED vertical chip 904 should be bonded to the backplane 902 but is not present. In an example, when the backplane 902 and the micro-LED vertical chips 904 are inspected and tested by the inspection device 900, defective micro-LED vertical chip 904e fails to illuminate (i.e., fails to emit light of the correct frequency and/or intensity). The AI based image analysis software also makes a record of locations, such as location 912, where a micro-LED vertical chip 904 is present but fails to illuminate (e.g., defective micro-LED vertical chip 904e). Making a record of locations 910 and 912 may include determining x and y coordinates on the backplane 902 indicating the locations. The x and y coordinates may be made with reference to a reference point on the backplane 902.

When the inspection device 900 has completed inspection and testing of the backplane 902, the AI based image analysis software may generate a set of maps regarding the backplane 902, according to embodiments of the present disclosure.

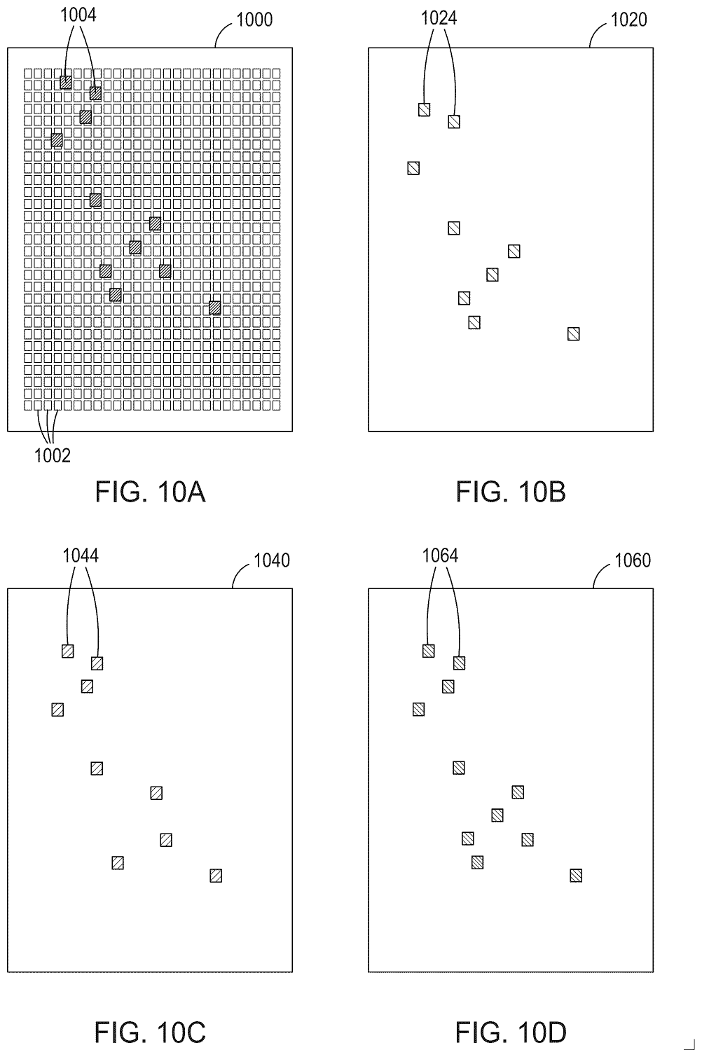

FIGS. 10A-10D depict a set of exemplary maps of a backplane 902 as created by the AI based image analysis software of the inspection device 900, according to embodiments of the present disclosure. FIG. 10A depicts a light-up/mechanical map 1000 of the backplane 902. In the light-up/mechanical map 1000, dots 1002 indicate locations on the backplane 902 where micro-LED vertical chips illuminated properly during an inspection and testing process, while dots 1004 indicate locations (e.g., locations 910 and 912) on the backplane 902 where a micro-LED vertical chip did not illuminate properly during the inspection and testing process.

FIG. 10B depicts a laser trim map 1020 of the backplane 902. In the laser trim map 1020, dots 1024 indicate locations (e.g., locations 912) on the backplane 902 where micro-LED vertical chips are present on the backplane 902, but did not illuminate properly during the inspection and testing process. There may be the same number or fewer dots 1024 on laser trim map 1020 than dots 1004 on light-up/mechanical map 1000.

FIG. 10C depicts a bump repair map 1040 of the backplane 902. In the bump repair map 1040, dots 1044 indicate locations (e.g., locations 910 or 912) on the backplane 902 where the AI based image analysis software determined to repair backplane electrodes. The dots 1044 on bump repair map 1040 may indicate the same or different locations than the dots 1024 indicate on laser trim map 1020. Bump repair map 1040 may indicate more, the same, or fewer locations that are indicated on laser trim map 1020.

FIG. 10D depicts a laser lift off (LLO) repair map 1060 of the backplane 902. In the LLO repair map 1060, dots 1064 indicate locations (e.g., locations 910 or 912) on the backplane 902 where the AI based image analysis software determined to install a repair micro-LED vertical chip. The dots 1064 on LLO repair map 1060 may indicate the same locations that the dots 1004 indicate on light-up/mechanical map 1000.

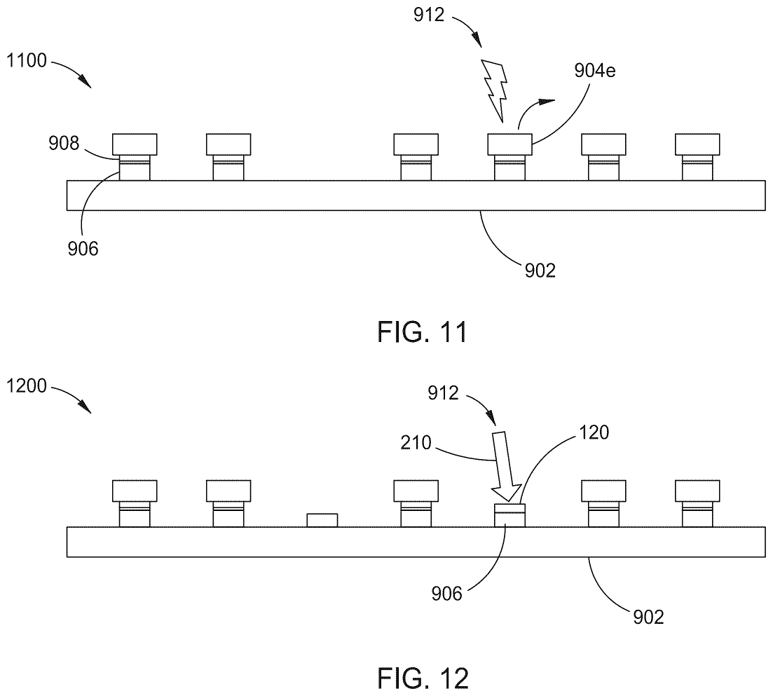

FIG. 11 schematically depicts a defective vertical chip laser trim-off operation 1100, according to embodiments of the present disclosure. The defective micro-LED vertical chip 904e is trimmed (e.g., using a laser) off the backplane 902. Defective micro-LED vertical chip 904e may be trimmed off the backplane 902 on the basis of defective micro-LED vertical chip 904e being located at location 912 on the backplane 902 and location 912 being among the locations indicated by dots 1024 on laser trim map 1020.

FIG. 12 schematically depicts a backplane bump repair operation 1200, according to embodiments of the present disclosure. In the backplane bump repair operation 1200, repair material 120 (e.g., indium or silver ink) is applied to the electrode 906 at location 912 by an applicator 1210 (e.g., an inkjet printer). Electrode 906 may be repaired based on the electrode 906 being located at location 912 on the backplane 902 and location 912 being among the locations indicated by dots 1044 on bump repair map 1040.

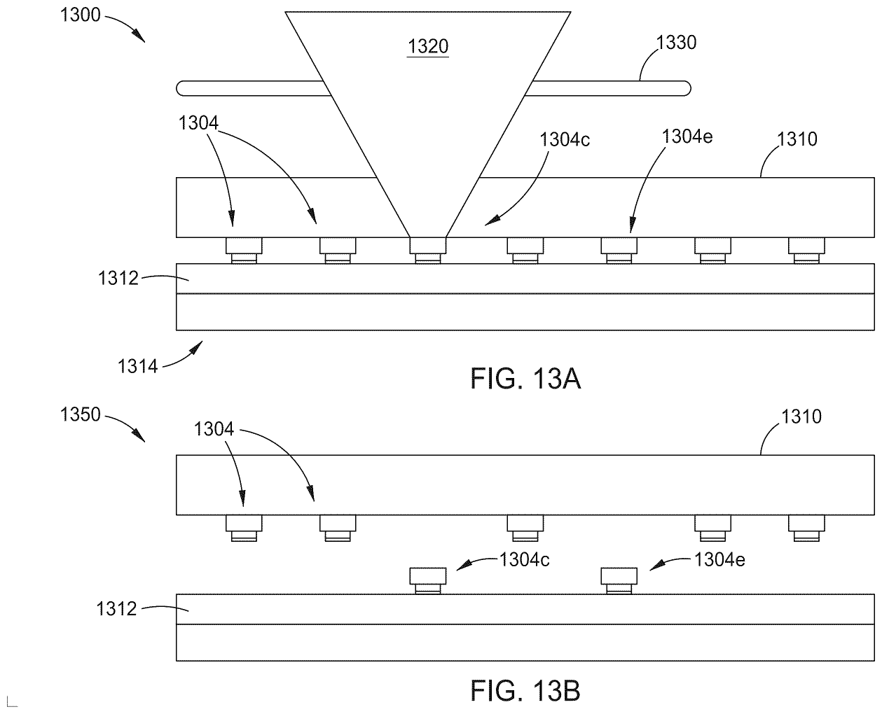

FIGS. 13A-13B schematically depict a repair laser lift off operation 1300 and a separation and transfer operation 1350, according to embodiments of the present disclosure. When the operation 1300 begins, a plurality of repair micro-LED vertical chips 1304 are bonded to a translucent carrier 1310 and to a first polymer 1312 of a first interposer 1314. The repair micro-LED vertical chips 1304 may be of the same type as the micro-LED vertical chips 904 shown in FIGS. 1 and 2. The translucent carrier 1310 may be made of sapphire, for example. During the operation 1300, laser light 1320 may be transmitted at the repair micro-LED vertical chips 1304. A mask 1330 may be formed on the basis of the LLO repair map 1060 so that only repair micro-LED vertical chips 1304 at locations indicated by the LLO repair map 1060 are exposed to the laser light 1320. Repair micro-LED vertical chip 1304c (as shown) and repair micro-LED vertical chip 1304e are exposed to the laser light 1320, which causes the repair micro-LED vertical chips 1304c and 1304e to debond from the translucent carrier 1310.

FIG. 13B schematically depicts the separation and transfer operation 1350, according to embodiments of the present disclosure. The translucent carrier 1310 is separated from the first interposer 1314 during the separation and transfer operation 1350. Repair micro-LED vertical chips 1304c and 1304e remain attached to the first polymer 1312, while the remaining repair micro-LED vertical chips 1304 remain bonded to the translucent carrier 1310.

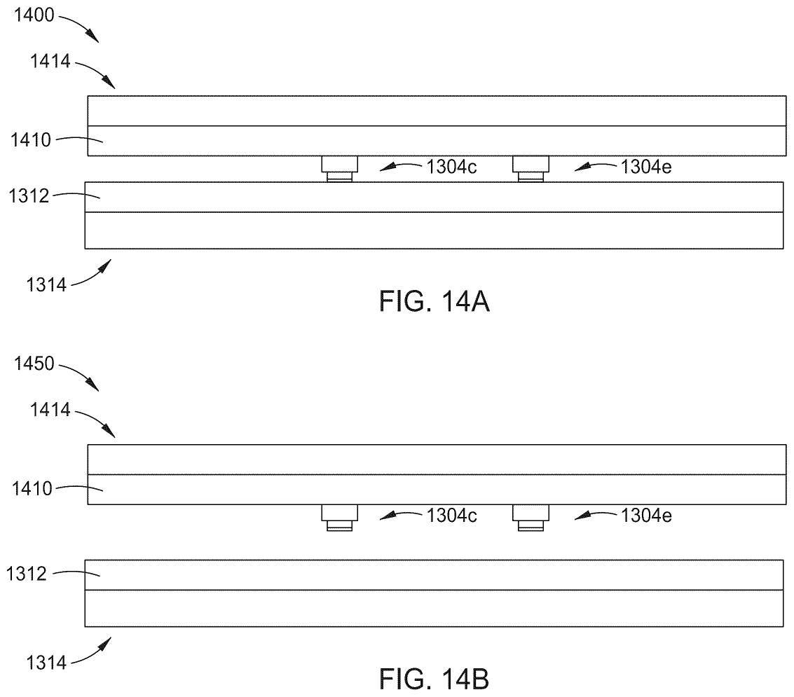

FIGS. 14A-14B schematically depict a laminating to second polymer operation 1400 and a separation and transfer operation 1450, according to embodiments of the present disclosure. During the laminating to second polymer operation 1400, repair micro-LED vertical chips on first polymer 1312 (e.g., repair micro-LED vertical chips 1304c and 1304e) are bonded to second polymer 1410 of a second interposer 1414.

FIG. 14B schematically depicts the separation and transfer operation 1450, according to embodiments of the present disclosure. The second polymer 1410 is separated from the first polymer 1312 during the separation and transfer operation 1450. Repair micro-LED vertical chips 1304c and 1304e remain bonded to the second polymer 1410 of second interposer 1414.

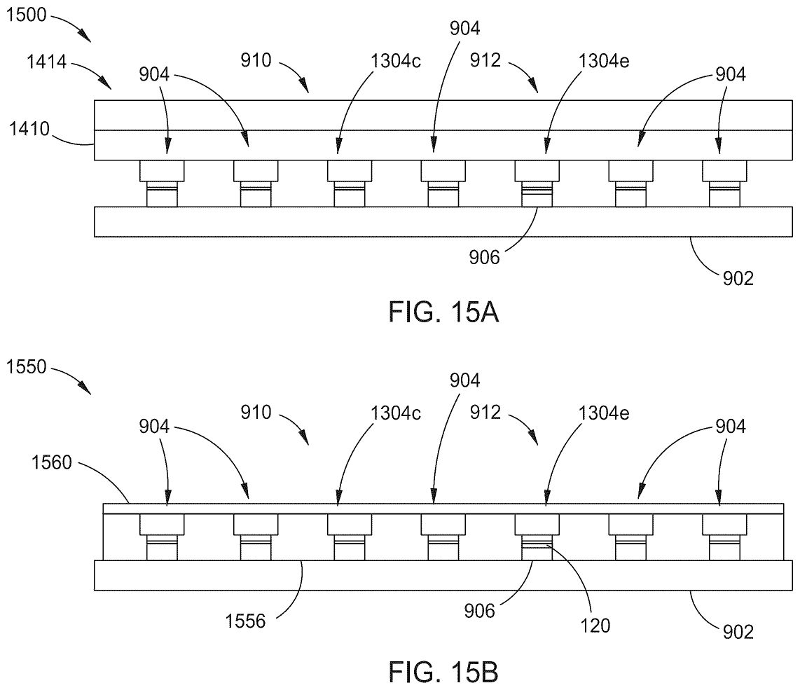

FIGS. 15A-15B schematically depict a repair bonding to backplane operation 1500 and a second polymer separation operation 1550, according to embodiments of the present disclosure. During the repair bonding to backplane operation 1500, repair micro-LED vertical chips (e.g., repair micro-LED vertical chips 1304c and 1304e) bonded to second polymer 1410 of second interposer 1414 are bonded with (e.g., soldered to) electrodes 906 on backplane 902. As depicted, the repair micro-LED vertical chips are bonded with electrodes 906 in locations (e.g., locations 910 and 912) on the backplane 902 that do not have micro-LED vertical chips 904 present. The repair micro-LED vertical chips may be bonded directly to electrodes 906 or to repair material 120 (e.g., indium or silver ink) applied to electrodes 906 during backplane bump repair operation 1200.

FIG. 15B schematically depicts the second polymer separation operation 1550, according to embodiments of the present disclosure. The second polymer 1410 is separated from the repair micro-LED vertical chips 1304c and 1304e during the second polymer separation operation 1550. Repair micro-LED vertical chips 1304c and 1304e remain bonded with the electrodes 906 on the backplane 902. After completion of the second polymer separation operation 1550, the backplane 902 may be considered repaired. The repaired backplane 902 may then be inspected and tested again, as described above with reference to FIG. 9. When the backplane 902 passes the inspection and testing process, a leak-tight filling or isolation material 1556 may be disposed between the micro-LED vertical chips 904 and the repair micro-LED vertical chips 1304. An indium tin oxide (ITO) coating 1560 may be applied on top of the isolation material 1556 and may form an electrical connection to electrodes at the top of the micro-LED vertical chips 904 and the repair micro-LED vertical chips 1304.

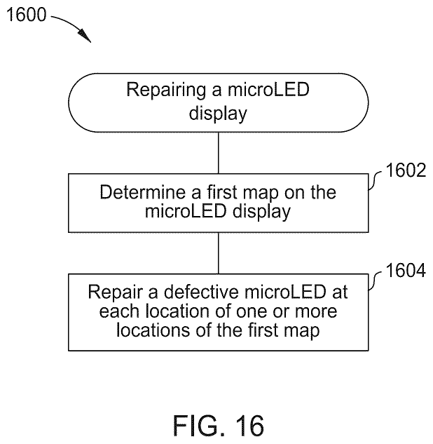

FIG. 16 is a flow diagram of a method 1600 of repairing a micro-LED display, such as a micro-LED display including the pixel 100 described herein.

Operation 1602 includes determining, by a processor, a first map of one or more locations on the micro-LED display. The first map including one or more locations of a defective micro-LED on the micro-LED display. A defective micro-LED includes a micro-LED that does not illuminate when supplied with electricity. For example, a processor of inspection device 200 may determine a light-up/mechanical map 300 of one or more locations (e.g., locations 210 and/or 212) on the micro-LED display that do not illuminate when supplied with electricity. In aspects of the present disclosure, the method 1600 further includes supplying electricity to the micro-LED display to determine the first map.

Operation 1604 includes repairing the defective micro-LED at each location of the one or more locations of the first map. to be installed at each of the one or more locations. Operation 1604 includes trimming the defective micro-LED off the backplane to expose a backplane electrode. A repair material is applied to the backplane electrode. A repair micro-LED 604 is disposed on the repair material. For example, the processor may cause a repair micro-LED 604 to be installed at each of the one or more locations (e.g., locations 210 and/or 212).

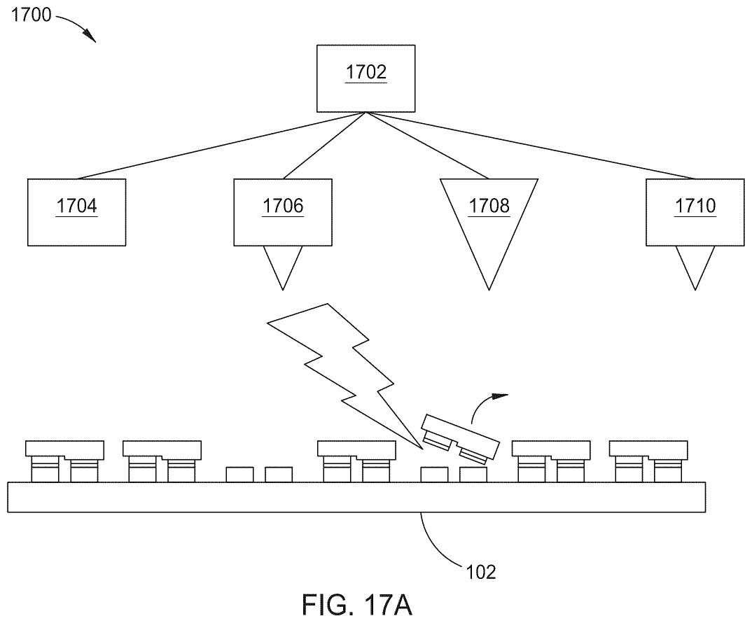

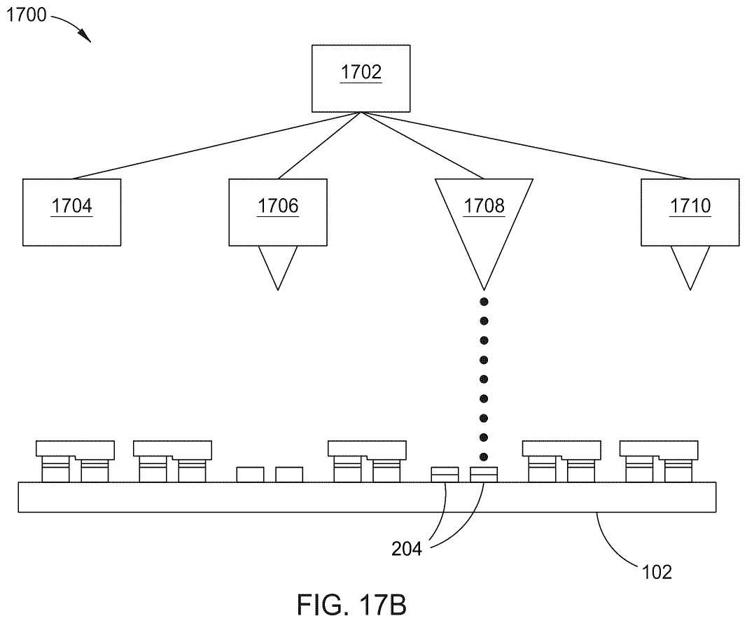

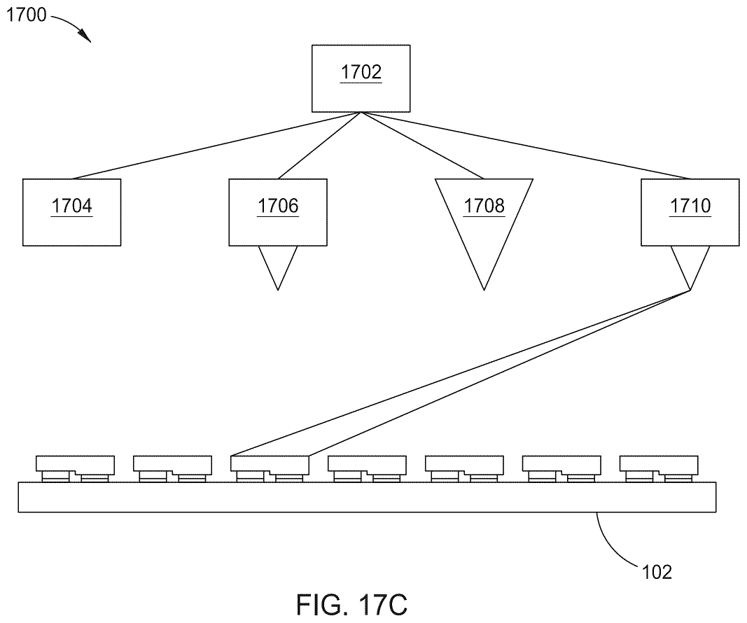

FIGS. 17A-17C show a system 1700 configured to perform one of more of the operations of method 1600. The system 1700 includes a controller 1702 communicatively coupled to an inspection device 1704. The controller 1702 can include one or more processors for processing signals received from the inspection device 1704. The inspection device 1704 may include one or more cameras and/or visual sensors. The controller 1702 may utilize an image analysis software or an artificial intelligence (AI) based image analysis software, according an embodiment of the present disclosure. The inspection device 1704 may transmit one or more visual images and/or data of the micro-LED 104 and/or backplane 102, in which the image analysis software or an software artificial intelligence (AI) based image analysis software makes a record of locations, where a micro-LED 104 should be bonded to the backplane 102 but is not present. In an example, when the backplane 102 and the micro-LED 104 are inspected by the inspection device 1702, the defective micro-LED die 104e fails to illuminate (i.e., fails to emit light of the correct frequency and/or intensity). The controller 1702, using the image analysis software, makes a record of locations, where a micro-LED 104 is present but fails to illuminate (e.g., the defective micro-LED die 104e). Making a record of may include determining x and y coordinates on the backplane 102 indicating the locations. The x and y coordinates may be made with reference to a reference point on the backplane 102. The controller 1702 may generate a set of maps regarding the backplane 102 using the image analysis software or an artificial intelligence (AI) based image analysis software, according to embodiments of the present disclosure.

The system 1700 includes a first laser 1706 communicatively coupled to the controller 1702, as shown in FIG. 17A. The system 1700, including the first laser 1706, may be used in operation 1604. For example, the first laser 1706 is configured to trim a micro-LED 104 on the micro-LED display based on the second map generated by the controller 1702, using the image analysis software. The first laser 1706 can include a laser suitable for separating a micro-LED 104 from the backplane 102 and/or backplane electrode 106.

The system 1700 includes an applicator 1708 communicatively coupled to the controller 1702, as shown in FIG. 17B. The system 1700, including the applicator 1708B may be used in operation 1604. For example, the applicator 1708 is configured to dispose a repair material to the micro-LED display based on the third map generated by the controller 1702, using the image analysis software. The applicator 1708 can include an applicator suitable for disposing a repair material on the backplane 102 and/or backplane electrode 106.

The system 1700 includes a second laser 1710 communicatively coupled to the controller 1702, as shown in FIG. 17C. The system 1700, including the applicator second laser 1710 may be used in operation 1604. For example, the second laser 1710 is configured to perform a laser light off on a repair micro-LED on a substrate based on the first map generated by the controller 1702, using the image analysis software. The second laser 1710 can include a laser suitable for perform a laser lift off on the repair micro-LED.

As used herein, “a processor,” “at least one processor,” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory,” or “one or more memories” generally refers to a single memory configured to store data and/or instructions, or multiple memories configured to collectively store data and/or instructions.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a backplane, the backplane having a plurality of backplane electrodes, each backplane electrode comprising a first material;
a plurality of micro-LEDs having a plurality of micro-LED electrodes, each micro-LED electrode comprising a second material, wherein each micro-LED electrode is bonded to each backplane electrode with an alloy of the first material and the second material therebetween, wherein at least one backplane electrode is bonded to the micro-LED electrode via a repair material; and
a plurality of subpixel isolation (SI) structures formed over the backplane, the SI structures defining wells of sub-pixels, each well including a respective micro-LED between adjacent SI structures, the sub-pixels having a color conversion material disposed in the wells.

2. The device of claim 1, wherein the repair material is conductive.

3. The device of claim 1, wherein the repair material comprises indium, silver, or combinations thereof.

4. The device of claim 1, wherein the first material comprises gold, indium, tin, silver, aluminum, platinum, or combinations thereof.

5. The device of claim 1, wherein the second material comprises gold, silver, aluminum, platinum, indium, or combinations thereof.

6. A method of repairing a micro-LED display, the method comprising:
determining a first map of the micro-LED display, wherein the first map comprises one or more locations of a defective micro-LED; and
repairing the defective micro-LED at each location of the one or more locations of the first map, wherein repairing the defective micro-LED comprises:
trimming the defective micro-LED from a backplane of the micro-LED to expose a backplane electrode;
disposing a repair material on the backplane electrode; and
disposing a repair micro-LED on the repair material.

7. The method of claim 6, further comprising:
determining a second map of the micro-LED display, wherein the second map comprises one or more locations of micro-LED on the micro-LED display; and
removing a micro-LED located at the one or more locations.

8. The method of claim 7, further comprising:
determining a third map of the micro-LED display, wherein the third map comprises one or more locations of electrodes on the micro-LED display; and
repairing an electrode located at the one or more locations.

9. The method of claim 6, wherein trimming the defective micro-LED comprises trimming the defective micro-LED using a first laser.

10. The method of claim 9, further comprising:
masking the repair micro-LED on a substrate in accordance with the first map; and
identifying an unmasked repair micro-LED on the substrate using a second laser.

11. The method of claim 6, wherein the repair material is conductive.

12. The method of claim 11, wherein the repair material comprises indium, silver, or combinations thereof.

13. The method of claim 6, wherein determining the first map further comprises supplying electricity to the micro-LED display to determine the first map.

14. A system comprising:
an inspection device operable to:
determine a first map of a micro-LED display;
determine a second map of the micro-LED display; and
determine a third map of the micro-LED display;
a first laser configured to trim a micro-LED on the micro-LED display based on the second map;
an applicator configured to dispose a repair material to the micro-LED display based on the third map; and
a second laser configured to perform a laser lift off on a repair micro-LED on a substrate based on the first map.

15. The system of claim 14, wherein the first map comprises one or more locations of a defective micro-LED.

16. The system of claim 14, wherein the second map comprises one or more locations of micro-LED on the micro-LED display.

17. The system of claim 14, wherein the third map comprises one or more locations of electrodes on the micro-LED display.

18. The system of claim 14, wherein the repair material is conductive.

19. The system of claim 18, wherein the repair material comprises indium, silver, or combinations thereof.

20. The system of claim 14, wherein determining the first map comprises supplying electricity to the micro-LED display to determine the first map.
